(19) United States
(12) Patent Application Publication
(10) Pub. No.: US 2024/0114760 A1
(43) Pub. Date: Apr. 4, 2024

(54) CLOSE SPACE ANNEALING METHOD AND METHOD FOR PREPARING PEROVSKITE FILM OR SOLAR CELL

(71) Applicant: SOOCHOW UNIVERSITY, Suzhou (CN)

(72) Inventors: Changlei WANG, Suzhou (CN); Dewei ZHAO, Suzhou (CN); Xiaofeng LI, Suzhou (CN)

(21) Appl. No.: 18/531,195

(22) Filed: Dec. 6, 2023

Related U.S. Application Data
(63) Continuation of application No. PCT/CN2023/074208, filed on Feb. 2, 2023.

(30) Foreign Application Priority Data
Apr. 26, 2022 (CN) 202210449863.1

(51) Int. Cl. H10K 71/40; H10K 30/10; H10K 71/15

(52) U.S. Cl. CPC H10K 71/441; H10K 30/10; H10K 71/15

(57) ABSTRACT

The invention provides a close space annealing method and a method for preparing a perovskite film or a solar cell. The method includes: placing a substrate coated with the perovskite precursor film on a hot plate, the hot plate being in direct contact with the back face of the substrate; controlling the evaporated amount and residual amount of the solvent in the perovskite precursor film by controlling the temperature of the hot plate and the heating duration, so that the perovskite materials are crystallized into perovskite grains to form a perovskite intermediate-phase film; placing the perovskite intermediate-phase film on the permeable membrane with the back face of the substrate facing upward, continuing with heating, so that adjacent perovskite grains merge with each other; and raising the temperature of the hot plate and continuing with heating so that the perovskite grains form a perovskite light-absorbing layer.

### FIELD OF THE INVENTION

The present invention relates to the field of solar cells, and in particular, to a perovskite film and a method for preparing the same.

### DESCRIPTION OF THE RELATED ART

Organic-inorganic hybrid perovskite has been widely studied and developed because of its superior photoelectric characteristics, and the efficiency of single-junction perovskite solar devices has increased from 3.8% to 25.7% in the last decade. Due to the limitation of Shockley-Queisser's limit of efficiency of single-junction photovoltaic devices, the potential in efficiency improvement of traditional single-junction perovskite solar cells is limited. Thanks to the high absorption coefficient of perovskite materials, planar perovskite photovoltaic devices show good light absorption characteristics, so complex processes such as surface texturing can be eliminated. This, combined with the wide bandgap tunability of perovskite, enables realization of multi-junction tandem solar cells. Obtaining high-efficiency photovoltaic devices by extending the absorption spectrum of photovoltaic materials and reducing the energy thermalization loss represents the next competition factor.

Although the efficiency of single-junction and double-junction tandem photovoltaic devices based on perovskite materials has made great progress, however, the actual efficiency of tandem solar cells still lag much behind the theoretical predicted values. This is mainly due to the poor crystallization quality, small grain size, numerous defect states and severe non-radiation recombination of perovskite light-absorbing films, which lead to poor efficiency of corresponding solar cells. Fabricating a high-quality perovskite light-absorbing layer is the prerequisite to achieve high efficiency single-junction solar cells and tandem solar cells. High-quality perovskite light-absorbing layer needs to meet the following criteria: 1) high crystallinity, that is, the grain size of perovskite needs to be large enough to improve the crystallization quality; 2) low defect state density, that is, the perovskite light-absorbing film should have fewer grain boundaries; 3) long carrier lifetime, so as to ensure that photo-generated carriers can reach the electrode through a long transport distance and avoid recombination loss.

Perovskite tandem solar cells need to meet requirement of high efficiency of both wide-bandgap top subcells and low-bandgap bottom subcells. On the one hand, it is necessary to add a lot of halogen bromine to increase the bandgap in preparing wide-bandgap perovskite films, which causes phase segregation inside perovskite materials, thus affecting the crystallization quality of perovskite films. On the other hand, it is necessary to obtain low-bandgap materials by doping tin ions (Sn²⁺) in preparing low-bandgap perovskite films. Because the crystallization speed of tin-based perovskite is too fast and is consequently difficult to be accurately controlled, which will lead to low crystallization quality, small grain size, poor film coverage and short carrier lifetime of low-bandgap perovskite, thus leading to a great number of grain boundaries and defects, which will affect the efficiency of low-bandgap perovskite solar cells.

For the perovskite materials mentioned above, the grain size and crystallization quality seriously affect the energy conversion efficiency of solar cells. The small grain size indicates that a great number of crystal nuclei are produced during perovskite crystallization, thus resulting in numerous grain boundaries. However, these grain boundaries usually show amorphous feature, and at the same time, they act as non-radiation recombination centers, causing severe recombination loss of photogenerated carriers, which in turn affects the performance of solar cells. Increasing the grain size of perovskite films and reducing the number of grain boundaries are necessary means to improvement of perovskite solar cells.

At present, the solutions to increasing the crystallinity of perovskite light-absorbing films mainly include: 1) using additives to increase the grain size of perovskite films; 2) adopting the solvent annealing solution by introducing an extra solvent to increase the grain size of perovskite film, and so forth. However, all the solutions mentioned above have some disadvantages.

First of all, the strategy of selection and use of additives is not suitable for all perovskites with different components due to the specific reactions between the additives and perovskites, and additives will introduce impurities, thus affecting the purity and phase stability of perovskite materials. For example, although the introduction of lead thiocyanate (Pb(SCN)₂) into low-bandgap perovskite has little effect on grain size increase, it causes lead iodide (PbI₂) to be introduced as an impurity.

Secondly, as shown in FIG. 1, the perovskite film has the following shortcomings: (1) The perovskite film has a small grain size and numerous grain boundaries; (2) The crystallization speed of the perovskite film is too fast, so it is difficult to control the content of solvent in the perovskite films, adjust the rate and direction of solvent volatilization, and manipulate the crystal growth process.

Thirdly, with regard to the solvent annealing solution, as shown in FIG. 2, for perovskite containing tin component, pin-holes will appear in the light-absorbing film, which has adverse effect on the coverage of the perovskite light-absorbing film and greatly reduces the power conversion efficiency of corresponding perovskite solar cell. Therefore, the current work to improve the crystallization quality of perovskite have some problems, such as uncontrollable grain size, complicated preparation process, poor universality and so on. The applicable perovskite components are limited, and the applicability to perovskite materials with different components is not good. No effort has been made to improve the crystallization quality of wide-bandgap perovskite, low-bandgap perovskite and regular-bandgap perovskite films at the same time.

### SUMMARY OF THE INVENTION

To solve the problem of inefficient photoelectric conversion due to poor crystallization quality of perovskite, the following technical solutions are adopted.

The invention provides a close space annealing method for preparing a perovskite light-absorbing layer, including the following steps:

Step (1): depositing a perovskite precursor solution on the front face of the substrate by spin coating process, and forming a perovskite precursor film on the front face of the substrate;

Step (2): placing the substrate coated with the perovskite precursor film on the front face on a hot plate, the hot plate being in direct contact with the back face of the substrate, so that heat is sequentially transferred to the substrate and the perovskite precursor film; setting the temperature of the hot plate to a first temperature, controlling the evaporated amount and residual amount of the solvent in the perovskite precursor film by controlling the first temperature and the heating duration, so that adjacent perovskite grains merge with each other during the volatilization process of the residual solvents, to form a perovskite intermediate-phase film; and

Step (3): overlaying the hot plate with a layer of permeable membrane, placing the perovskite intermediate-phase film on the permeable membrane with the back face of the substrate facing upward, keeping the first temperature and continuing with heating, so that adjacent boundaries between perovskite grains dissolve and melt with each other when the residual solvent volatilizes; raising the temperature of the hot plate slowly to a second heating temperature and continuing with heating, so that the perovskite grains undergo phase change to form a well-crystallized perovskite light-absorbing layer.

The perovskite precursor solution is a solution mixture formed by a perovskite precursor material and a solvent, and the optical bandgap range of the perovskite material is between 1.2 and 2.3 electron volts (eV). Preferably, the perovskite material is selected from the group consisting of methylammonium lead iodine (MAPbI₃), methylammonium lead bromide (MAPbBr₃), formamidinium lead iodide (FAPbI₃), formamidinium lead bromide (FAPbBr₃), formamidinium tin iodide (FASnI₃), cesium lead iodide (CsPbI₃), cesium lead bromide (CsPbBr₃) and any combination thereof.

For the perovskite precursor solution, strong polar solvent and perovskite precursor material are used to form a stable solution mixture by Lewis acid-base method. The strong polar solvent is selected from the group consisting of dimethyl sulfoxide, dimethylformamide, gamma butyrolactone and any combination thereof.

Preferably, the spin coating in step (1) includes two steps. In the first step, the spinning speed is set to 500-1000 rpm and the duration is set to 2-10 seconds for the spin coating, and in the second step, the spinning speed is set to 3000-5000 rpm, and the duration is set to 1 minute for the spin coating. An anti-solvent is dripped at the 4-30 seconds after start of spinning in the second step. In preparing the precursor film, the anti-solvent can accelerate the surface crystallization process, realize rapid heterogeneous nucleation on the surface of perovskite intermediate-phase film, and avoid the rough surface formed when the crystallization speed of perovskite exceeds the nucleation speed, thus ensuring the flatness and grain morphology of the perovskite intermediate-phase film.

The anti-solvent is a weak polar solvent. Preferably, the weak polar solvent includes diethyl ether, or is selected from the group consisting of chlorobenzene, ethyl acetate, isopropanol and any combination thereof.

Preferably, in step (2), the first temperature is 60-70° C. and the heating duration is 10-50 seconds; and in step (3), the heating duration at the first temperature is 2-4 minutes; and the second heating temperature is 80-120° C., and the heating duration is 6-15 minutes at the second heating temperature.

Preferably, the method also includes step (4): placing the substrate on the hot plate with the front face facing upward, the hot plate being in direct contact with the back face of the substrate, and maintaining the second heating temperature for a heating duration of 1-3 minutes. This process causes the residual solvent to continue to volatilize and ensures that there is no residual organic solvent in the crystallized perovskite light-absorbing layer, thereby ensuring the good crystallization quality inside the perovskite crystals.

Further, the permeable membrane is selected from the glass sheet, filter paper or printing paper. Different permeable membranes as selected have different release rates of the internal solvent in the perovskite, which affects the volatilization rate and the involvement content of the internal solvent in the perovskite intermediate-phase film, and consequently affects the grain size of perovskite. The permeability of the permeable membrane has a negative correlation with its effect on the grains. The higher the permeability, the smaller the grain size.

Preferably, the hot plate may be a program-controlled hot plate, on which the real-time temperature can be set and displayed, to ensure that the variation in the surface temperature of the heating table can be obtained more accurately.

Preferably, the permeable membrane is made of filter paper.

In the present application, a perovskite precursor solution is spin-coated on a substrate to form a perovskite precursor film, which contains a large amount of solvent that will volatilize in the subsequent heating process. The first temperature is used for preheating, and the residual amount of the solvent described above is accurately adjusted by controlling the heating temperature and heating duration. A perovskite crystalline state is formed through ion exchange, thereby forming a perovskite intermediate-phase film. The substrate is placed on the permeable membrane of the hot plate with the back face facing upward and is reheated at the first temperature, where a certain confined area is formed between the perovskite intermediate-phase film, the permeable membrane and the hot plate. This confined area can affect the volatilization path and rate of residual internal solvent in the perovskite intermediate-phase film. In the heating process, the volatilization path of the residual solvent in the perovskite intermediate-phase film is blocked, and then the residual solvent will be slowly released in the confined space and exchange positions with organic cations to cause transition from intermediate-phase to crystalline phase. At this time, the previously formed perovskite grain boundaries will melt with each other by means of the dissolution and recrystallization process of the residual solvent, and the adjacent small perovskite grains will be combined together through the Ostwald ripening process and the ordered adsorption process, thus forming larger perovskite grains. The permeable membrane will change the volatilization direction and ratio of the residual solvent. The solvent volatilization direction generally divides into two directions: horizontal volatilization and vertical releasing. The horizontal process will expand the horizontal size of perovskite grains, and the vertical diffusion process can increase the grain size without horizontal grain boundaries across the film. Heating is continued to anneal the perovskite intermediate-phase film to the second temperature, and the heat-up rate and final temperature are controlled by a program. After reaching the phase change temperature for perovskite crystallization, the crystallization process completed by merging small grains into big ones, forming a large-grain and high-quality perovskite light-absorbing layer, thereby reducing the number of grain boundaries, inhibiting the formation of defects, prolonging the lifetime of photo-generated carriers and ensuring the high performance of the perovskite light-absorbing layer.

The method of the present invention is suitable for preparing perovskite films with different components. It can avoid the influence of external solvents on the perovskite light-absorbing layer, and address the issue that the crystallization of the perovskite light-absorbing layer is out of control. At the same time, this close space annealing method avoids the selectivity of the process of additive or solvent annealing or the like with regard to perovskite materials, has better compatibility with different perovskite components, and is more advantageous than the prior art for application to large-area preparation.

### BRIEF DESCRIPTION OF THE DRAWINGS

FIG. 1 is a schematic diagram showing normal annealing in the prior art;

FIG. 2 is a schematic diagram showing solvent annealing in the prior art;

FIG. 3 is a schematic diagram showing heating in the method for preparing a perovskite film of the present application;

FIG. 4 shows scanning electron microscope images of perovskite films obtained by different annealing methods;

In this figure, (A) represents a normal annealing method; (B) represents a solvent annealing method, and (C) represents a method for preparing a perovskite film according to the present application;

FIG. 5 shows scanning electron microscope images of perovskite films prepared by different methods,

In this figure: (D) represents a normal annealing method; (E) represents a method in which glass is selected as the permeable membrane, (F) represents a method in which filter paper is selected as the permeable membrane, and (G) represents a method in which printing paper is selected as the permeable membrane;

FIG. 6 is a schematic diagram showing the effect of different permeable membranes on grain growth;

FIG. 7 is a schematic diagram showing melting of grains with each other in the perovskite intermediate-phase film;

FIG. 8 shows Fourier transform infrared (FTIR) spectroscopy of low-bandgap perovskite films obtained at 65° C. for different preheating durations;

FIG. 9 shows scanning electron microscope images of low-bandgap perovskite films prepared at 65° C. for different preheating durations;

In this figure: (H) the preheating duration is 0 seconds, (I) the preheating duration is 10 seconds, (J) the preheating duration is 20 seconds, (K) the preheating duration is 30 seconds, (L) the preheating duration is 40 seconds, and (M) the preheating duration is 50 seconds;

FIG. 10 is a schematic diagram of a low-bandgap perovskite solar cell;

FIG. 11 is the J-V curves of solar cells prepared from the 1.25 eV low-bandgap perovskite light-absorbing layers based on different annealing methods;

FIG. 12 is a schematic diagram of a wide-bandgap perovskite solar cell;

FIG. 13 is the J-V curves of solar cells prepared from the 1.75 eV wide-bandgap perovskite light-absorbing layers based on different annealing methods;

FIG. 14 is a schematic diagram of an all-perovskite tandem solar cell; and

FIG. 15 shows J-V curves of all perovskite two-terminal tandem solar cells prepared from a 1.75 eV wide-bandgap perovskite light-absorbing layer and a 1.25 eV low-bandgap perovskite light-absorbing layer based on different annealing methods.

### DETAILED DESCRIPTION OF THE PREFERRED EMBODIMENTS

In order to provide clearer understanding of the objects, technical solutions and advantages of the present application, the present application will be further described below in detail with the accompanying drawings. Hereinafter, the terms “first” and “second” and so on are intended for descriptive purposes only, and shall not be understood as indicating or implying relative importance or implicitly indicating the number of indicated technical features. Thus, the features defined by “first”, “second” and so on may explicitly or implicitly include one or more of these features.

### Embodiment 1

A method for preparing a low-bandgap perovskite film is provided. The low-bandgap perovskite film has a planar structure and includes a substrate and a perovskite light-absorbing layer. The substrate consists of a conductive substrate and a carrier transport layer deposited on the front face thereof. The preparation method includes the following steps:

Step (1): A perovskite precursor solution is deposited on the substrate by spin coating to form a perovskite precursor film on the surface of the carrier transport layer. The perovskite precursor solution is a solution mixture formed by a perovskite precursor material and a solvent. The perovskite precursor film contains a great amount of solvent.

Step (2): The substrate is placed on a hot plate with the front face facing upward. The hot plate is in direct contact with the back face of the substrate. Heat is sequentially transferred to the conductive substrate, the carrier transport layer and the perovskite precursor solution film. The temperature of the hot plate is set to a first temperature. The evaporated amount and residual amount of the solvent in the perovskite precursor film are controlled by controlling the first temperature and the heating duration. The perovskite precursor film is crystallized into perovskite grains on the surface of the carrier transport layer, so as to form a perovskite intermediate-phase film.

Step (3): The hot plate is overlayed with a layer of permeable membrane. The perovskite intermediate-phase film containing residual solvents is placed on the permeable membrane with the back face of the substrate facing upward. The temperature is kept at the first temperature and heating is continued, so that adjacent perovskite grains merge with each other during the volatilization process of the residual solvents. The temperature of the hot plate is raised slowly to a second heating temperature and heating is continued, so that the perovskite grains undergo phase change to form the low-bandgap perovskite light-absorbing layer.

Preferably, the conductive substrate is selected from the group consisting of an ITO glass substrate, an FTO glass substrate, a flexible ITO substrate and any combination thereof.

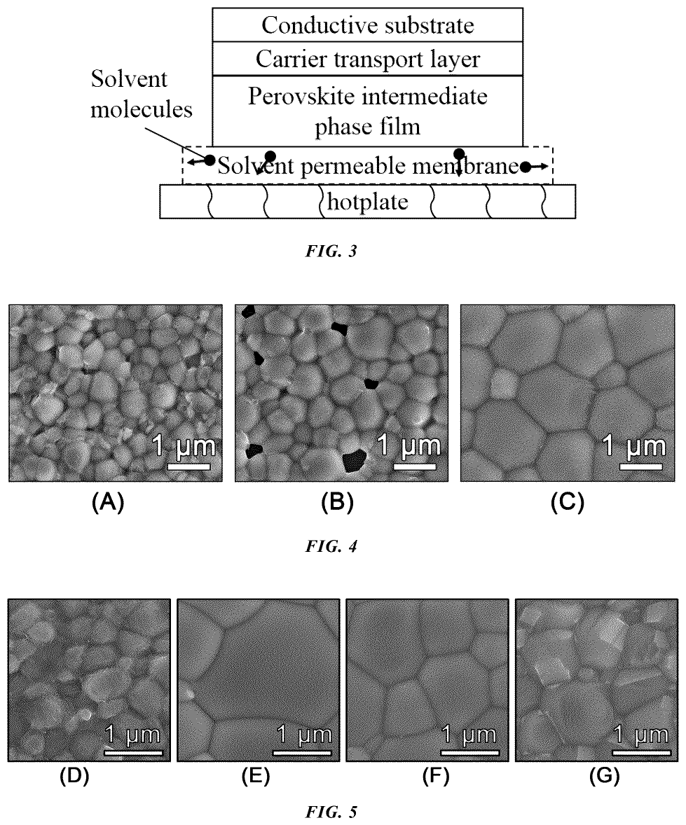

More specifically, in step (2), the first temperature is 65° C. and the heating duration is 30 seconds. In step (3), filter paper is selected as the permeable membrane, as shown in FIG. 3, and the heating duration is 2-4 minutes at the first temperature; and the temperature of the hot plate is slowly raised to the second heating temperature of 100° C. and heating is continued for 7 minutes.

The preparation steps by use of normal annealing and solvent annealing in the prior art are presented below respectively for comparison with the technical solution of this embodiment.

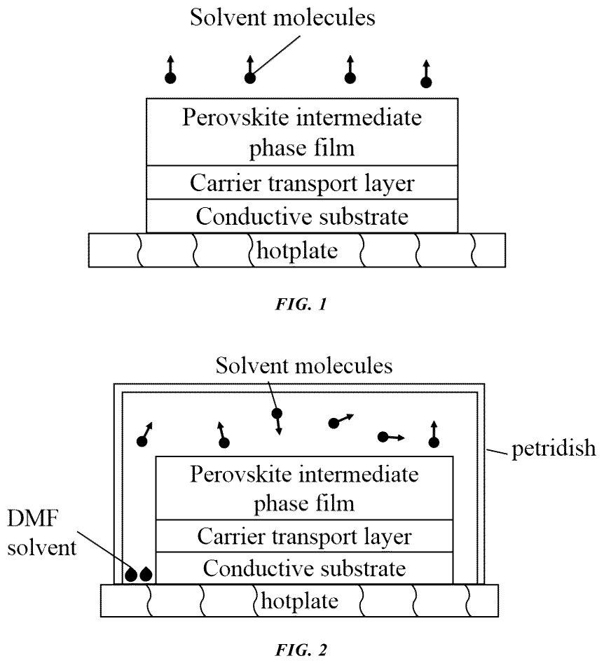

As shown in FIG. 1, the method for preparing a low-bandgap perovskite film by the normal annealing method in the prior art includes the following steps:

(1) A hole transport material is spin-coated on a cleaned conductive substrate to obtain a hole transport layer through annealing.

(2) A low-bandgap perovskite precursor film is prepared by spin coating low-bandgap perovskite materials on the substrate in step (1) by the anti-solvent method, and the specific spin coating parameters include a low speed of 1000 rpm and a duration of 10 seconds, a high speed of 4000 rpm and a duration of 60 seconds, and the anti-solvent diethyl ether is dripped at the 7th second during the high speed period to obtain a wet perovskite intermediate-phase film.

(3) The perovskite intermediate-phase film obtained in step (2) is subjected to normal annealing treatment with the front face of the substrate facing upward. First, the hot plate is heated at 65° C. for 3 minutes; and thereafter, the perovskite intermediate-phase film is transferred to a hot plate at 100° C. and continues to be heated for 7 minutes to obtain a low-bandgap perovskite light-absorbing film

As shown in FIG. 2, the method for preparing a low-bandgap perovskite film by the solvent annealing method in the prior art includes the following steps:

(1) A hole transport material is spin-coated on a cleaned conductive substrate to obtain a hole transport layer through annealing.

(2) A low-bandgap perovskite light-absorbing layer is prepared by spin coating low-bandgap perovskite materials on the substrate in step (1) by the anti-solvent method, and the specific spin coating parameters include a low speed of 1000 rpm and a duration of 10 seconds, and a high speed of 4000 rpm and a duration of 60 seconds, and the anti-solvent diethyl ether is dripped at the 7th second during the high speed period to obtain a wet perovskite intermediate-phase film.

(3) The perovskite intermediate-phase film obtained in step (2) is subjected to solvent annealing treatment, and the substrate is placed on a hot plate at the room temperature with the surface of the intermediate-phase film facing upward, at which point the hot plate has not yet started to operate. A certain amount of dimethylformamide solvent (such as 10 microliters) is dripped 1 cm away from the perovskite intermediate-phase film, and then a glass petri dish is used to cover the perovskite intermediate-phase film and the dimethylformamide solution. After that, the heating program of the hot plate is started at a heat-up rate of about 40° C./min. Upon reaching the temperature of 65° C., the system is stabilized for 3 minutes. After that, the temperature of the hot plate is raised to 100° C. and kept for 7 minutes. It can be observed that volatilization of the dimethylformamide solvent is gradually completed, so the intermediate-phase film transformed to be a low-bandgap perovskite film upon annealing in the presence of dimethylformamide solvent.

The low-bandgap perovskite light-absorbing films prepared by three methods, i.e., the normal annealing, the solvent annealing and the method for preparing a perovskite film in the present application, are shown in FIG. 4. (A) represents the perovskite light-absorbing film prepared by normal annealing. It has an average grain size of about 400 nm and a big deviation of grain size distribution. This indicates that the film has poor crystallization quality and numerous grain boundaries, which will further affect the recombination of photo-generated carriers and is unfavorable for the transportation of photo-generated carriers. (B) represents the perovskite light-absorbing film obtained by solvent annealing. It has significantly increased grain size, an average grain size of 500 nm, and a decreased number of grain boundaries. However, some voids have been introduced, indicating that the dimethylformamide solvent that is additionally introduced destroyed the as-formed grains, so the appearance of voids causes increased recombination of photo-generated carriers in the transportation process. (C) represents the perovskite film obtained by the method for preparing a perovskite film in the present application. It has significantly increased grain size, an average grain size of 1000 nm, a significantly decreased number of grain boundaries, improved crystallization quality, and a flat and homogeneous surface of the perovskite film, which is beneficial to inhibiting generation of defect states and facilitates transportation of photo-generated carriers.

The filter paper, glass and printing paper have different permeabilities, which leads to different effects on the volatilization process of solvent molecules in the perovskite intermediate-phase films. In order to compare the effects of different permeable membranes on the preparation of perovskite films, the permeable membrane mentioned in step (3) of the method for preparing a perovskite film in the present application is replaced with glass and printing paper respectively.

FIG. 5 shows scanning electron microscope images of perovskite films prepared by different methods. Among them, (D) represents a perovskite film prepared by normal annealing, presented here for comparison. It has a perovskite grain size of about 400 nm and numerous grain boundaries. (E) represents a low-bandgap perovskite light-absorbing film prepared by the method for preparing a perovskite film in the present application in which glass is selected as the permeable membrane. It has an average grain size of about 1500 nm, a smooth grain surface and a decreased number of grain boundaries. (F) represents a low-bandgap perovskite light-absorbing film obtained by the close space annealing method in the present application in which filter paper is selected as the permeable membrane. It has a grain size of about 1000 nm and a certain domain texture on the grain surface, indicating good crystallization state. (G) represents a low-bandgap perovskite light-absorbing film prepared by the close space annealing method in the present application in which printing paper is selected as the permeable membrane. It has a grain size of about 900 nm and a certain number of small-sized grains near the grain boundary, which affects the transportation of photo-generated carriers.

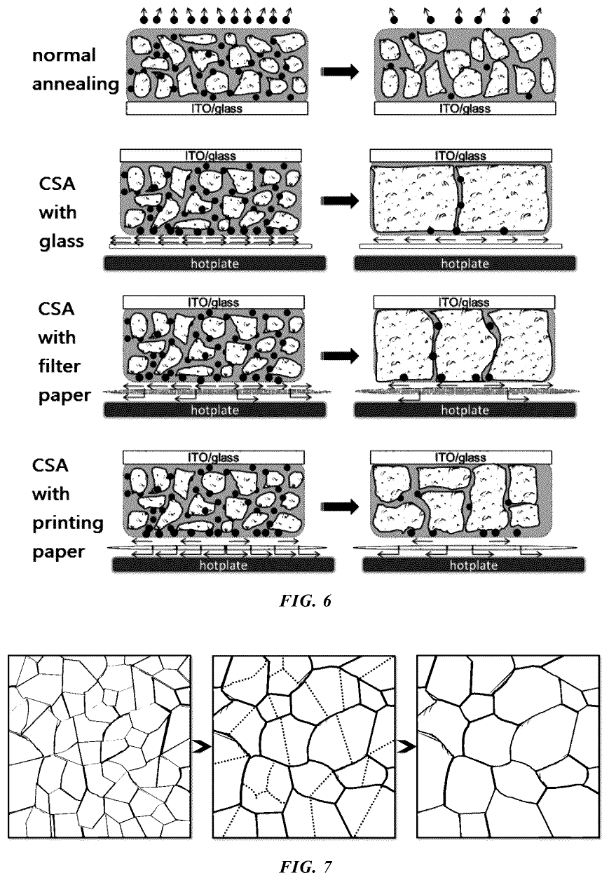

As shown in FIG. 6, with the normal annealing method, the volatilization direction of solvent molecules in the perovskite intermediate-phase film is vertically upward, so it is not affected by space confinement, and the solvent has little effect on the lateral growth of grains. With the close space annealing method, when the substrate where the perovskite intermediate-phase film is positioned is placed on different permeable membranes for annealing with the back face facing upward, the volatilization process of internal solvent molecules varies due to the different volatilization rates of the three permeable membranes in the horizontal and vertical directions. For close space annealing of glass, the internal solvent molecules in the perovskite intermediate-phase film only volatilize in the horizontal direction, which can increase the horizontal melting of grains, but the solvent molecules do not volatilize in the vertical direction, and the grain surface has no texture. For close space annealing of filter paper, the internal solvent molecules in the perovskite intermediate-phase film have both horizontal component and vertical component. The experiment shows that the volatilization rate of solvent in the horizontal direction is higher than that in the vertical direction. The transverse volatilization of solvent can facilitate the horizontal melting between perovskite grains and increase the grain size, while the vertical volatilization of solvent molecules will affect the ordered texture of the surface. For close space annealing of printing paper, the internal solvent molecules in the perovskite intermediate-phase film also have both horizontal and vertical components. The experiment shows that the volatilization rate of the solvent in the horizontal direction is lower than that in the vertical direction, and the horizontal volatilization of the solvent facilitates melting between grains and increase the grain size, and the vertical volatilization of the solvent is dominant, which is beneficial to the formation of texture in the grain surface.

Taking the example of the close space annealing method in which filter paper is selected as the permeable membrane, referring to the schematic diagram showing melting of grains with each other in the perovskite intermediate-phase film in FIG. 7. FIG. 7 shows the first temperature stage, confinement growth stage and final crystallization state of the perovskite intermediate-phase film from left to right. The first temperature is used for preheating. In this stage, the grain size of the perovskite intermediate-phase film is small, and the internal solvent volatilizes in the vertical direction to control the residual content of the internal solvent. In the confinement growth stage, the internal solvent volatilizes in the horizontal direction on the surface of the perovskite intermediate-phase film to dissolve the original grain boundary, so that adjacent small grains are merge together and grow into large grains. Annealing is continued, so that all the residual solvents are completely volatilized, and the perovskite film completes the change from intermediate-phase to crystalline phase, that is, the perovskite light-absorbing film with large grains and high quality is formed.

The perovskite light-absorbing layer absorbs incident light efficiently, generates photo-generated electron-hole pairs, and diffuses to the carrier transport layer. The carrier transport layer is arranged between the conductive substrate and the perovskite light-absorbing layer and is configured to transport carriers collected in the perovskite light-absorbing layer to the conductive substrate. The conductive substrate is configured to collect the carriers and transport them to an external circuit and has the functions of both light transmission and supporting. The carrier transport layer can be replaced by a planar electron transport layer or a hole transport layer as required, thus forming other perovskite films.

### Embodiment 2

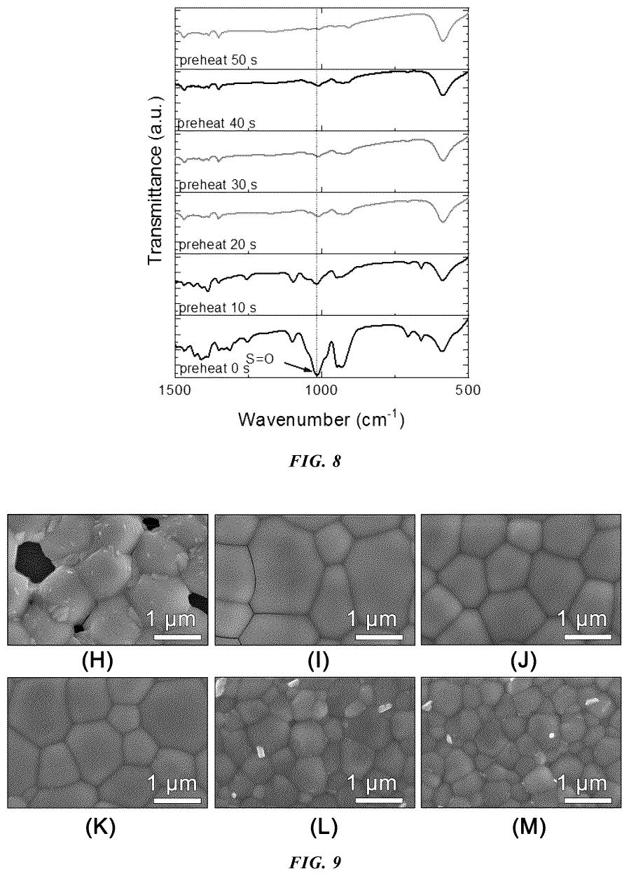

The heating duration at the first temperature in step (2) in the first embodiment is adjusted to 0 seconds, 10 seconds, 20 seconds, 30 seconds, 40 seconds and 50 seconds respectively, and the internal molecular vibration spectrum of the perovskite intermediate-phase film is obtained by testing with a Fourier transform infrared transmission spectrometer, as shown in FIG. 8. In this molecular vibration spectrum, when the wave number is 1016 cm⁻¹, the vibration characteristic peak of sulfur-oxygen double bond (S═O) is obtained. As the preheating duration increases from 0 seconds to 50 seconds, the vibration intensity of the sulfur-oxygen double bond varies from strong to weak, indicating that the content of the residual internal solvent in the perovskite intermediate-phase film is reduced, thereby realizing accurate control of the internal solvent in the perovskite intermediate-phase film.

As shown in FIG. 9, the scanning electron microscope images of low-bandgap perovskite light-absorbing films are obtained by varying the preheating durations with the close space annealing method in which filter paper is selected as the permeable membrane. (H) represents the low-bandgap perovskite light-absorbing film obtained by preheating for 0 seconds. It has an average grain size of 1200 nm and large voids at the grain boundaries. (I) represents the low-bandgap perovskite light-absorbing film obtained by preheating for 10 seconds. It has an average grain size of 1500 nm and a smooth grain surface. (J) represents the low-bandgap perovskite light-absorbing film obtained by preheating for 20 seconds. It has an average grain size of 1100 nm and a smooth grain surface. (K) represents a low-bandgap perovskite light-absorbing film obtained by preheating for 30 seconds. It has an average grain size of 1100 nm and a textured pattern on the grain surface. (L) represents the low-bandgap perovskite light-absorbing film obtained by preheating for 40 seconds. It has an average grain size of 800 nm, particles on the grain surface, and uneven grain sizes. (M) represents the low-bandgap perovskite light-absorbing film obtained by preheating for 50 seconds. It has an average grain size of 500 nm and numerous grain boundaries.

### Embodiment 3

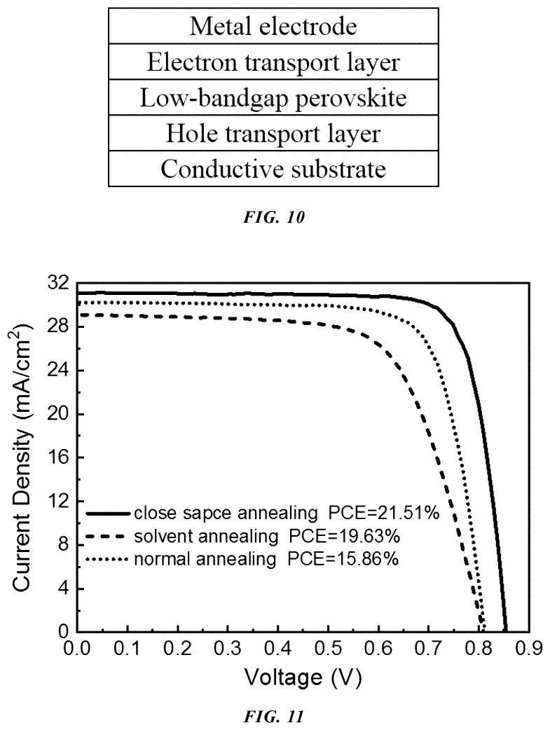

A method for preparing a low-bandgap perovskite solar cell is provided. As shown in FIG. 10, this low-bandgap perovskite solar cell has a planar composite layer structure, including a substrate, a perovskite light-absorbing layer, an electron transport layer and a metal electrode. The substrate consists of a conductive substrate and a hole transport layer arranged on the front surface of the conductive substrate. The preparation method includes the following steps:

Step (1) A perovskite precursor solution is deposited on a substrate by spin coating to form a perovskite precursor film on the surface of the hole transport layer.

Spin coating parameters include a low speed of 1000 rpm and a duration of 10 seconds, and a high speed of 4000 rpm and a duration of 60 seconds, and anti-solvent diethyl ether is dripped at the 7th second during high speed period.

Step (2) The substrate coated with perovskite precursor film is placed on the hot plate with the front surface of the film facing upward, and is heated at a first temperature of 65° C. for 30 seconds to obtain a perovskite intermediate-phase film.

Step (3) The hot plate is overlayed with a layer of permeable membrane. A perovskite intermediate-phase film containing residual solvent is placed on the permeable membrane with the back face of the substrate facing upward, and the film is heated at the first temperature for 3 minutes, and then the temperature is raised to a second temperature of 100° C. at a heat-up rate of 40° C./min, and heating is maintained for 7 minutes after reaching 100° C.

Step (4) The substrate is placed on the hot plate with the front face facing upward and heating is continued at a second temperature of 100° C. for 3 minutes to obtain a perovskite light-absorbing layer.

Step (5) An electron transport layer consisting of a C60 layer of 20 nm coupled with a BCP layer of 8 nm is deposited on the surface of the perovskite light-absorbing layer by thermal evaporation.

Step (6) A metal electrode of 100 nm is deposited on the surface of the electron transport layer by thermal evaporation to finally obtain a low-bandgap perovskite solar cell.

The performance of the obtained low-bandgap perovskite solar cell is tested by simulated sunlight irradiation with a power intensity of 100 mW/cm². The specific conditions of J-V measurement include a scanning voltage range of −0.1-0.93 V, a step size of 10 mV, and a scanning speed of 150 mV/s.

As comparison, step (3) of this embodiment is replaced by the normal annealing method, and the perovskite intermediate-phase film is placed on a hot plate at 65° C. and heated for 3 minutes, then transferred to a hot plate at 100° C. and heated for 7 minutes, so as to obtain the normally annealed low-bandgap perovskite light-absorbing film.

As comparison, step (3) of this embodiment is replaced by the solvent annealing method, and the perovskite intermediate-phase film is placed on a hot plate at room temperature, 10 microliters of dimethylformamide solvent is dripped at a distance of 1 cm from the perovskite intermediate-phase film, the glass petri dish is used to cover the perovskite intermediate-phase film and the solvent, the heating switch of the hot plate is turned on to heat up at a rate of 40° C./min, the temperature is raised to 65° C. and heating is maintained for 3 minutes, and the hot plate continues to heat up to 100° C. and heating is maintained for 7 minutes, so as to obtain the solvent-annealed low-bandgap perovskite light-absorbing film.

As can be seen from FIG. 11, the low-bandgap perovskite solar cell prepared by close space annealing has the highest efficiency, up to 21.51%. The low-bandgap perovskite solar cell prepared by normal annealing has slightly lower efficiency, of 19.63%. The low-bandgap perovskite solar cell prepared by solvent annealing has the lowest efficiency, of only 15.86%.

### Embodiment 4

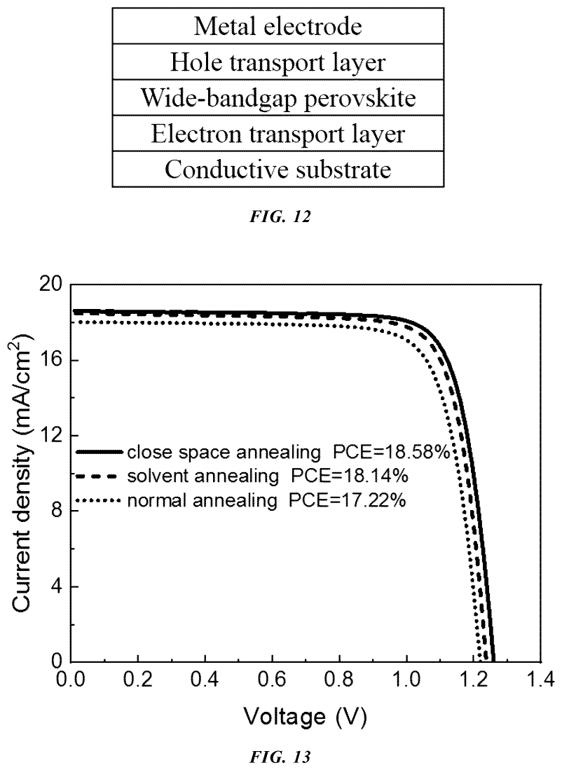

A method for preparing a wide-bandgap perovskite solar cell is provided. As shown in FIG. 12, this wide-bandgap perovskite solar cell has a planar structure, including a substrate, a perovskite light-absorbing layer, a hole transport layer and a metal electrode. The substrate consists of a conductive substrate and an electron transport layer deposited on the front face thereof. The preparation method includes the following steps:

Step (1) A perovskite precursor solution is deposited on a substrate by spin coating to form a perovskite precursor film on the surface of the electron transport layer.

Spin coating parameters include a low speed of 500 rpm and a duration of 3 seconds, and a high speed of 4000 rpm and a duration of 60 seconds, and anti-solvent diethyl ether is dripped at the 25th second during high speed period.

Step (2) The substrate is placed on a hot plate with the front face facing upward, and is heated at a first temperature of 65° C. for 3 minutes to obtain a perovskite intermediate-phase film.

Step (3) The hot plate is overlayed with a layer of permeable membrane. A perovskite intermediate-phase film containing residual solvent is placed on the permeable membrane with the back face of the substrate facing upward, and the film is heated at the first temperature for 3 minutes, and then the temperature is raised to a second temperature of 100° C. at a heat-up rate of 40° C./min, and heating is maintained for 7 minutes after reaching 100° C.

Step (4) The substrate is placed on the hot plate with the front face facing upward and continues to be heated at a second temperature of 100° C. for 3 minutes to obtain a perovskite light-absorbing layer.

Step (5) A hole transport layer is deposited on the surface of the perovskite light-absorbing layer by spin coating.

Step (6) A metal electrode is deposited on the surface of the hole transport layer by thermal evaporation to finally obtain a wide-bandgap perovskite solar cell.

The performance of the obtained low-bandgap perovskite solar cell is tested by simulated sunlight irradiation with a power intensity of 100 mW/cm². The specific conditions of J-V measurement include a scanning voltage range of −0.1-1.3 V, a step size of 10 mV, and a scanning speed of 150 mV/s.

As comparison, step (3) of this embodiment is replaced by the normal annealing method, and the perovskite intermediate-phase film is placed on a hot plate at 65° C. and heated for 3 minutes, then is transferred to a hot plate at 100° C. and continues to be heated for 10 minutes, so as to obtain a normally annealed wide-bandgap perovskite light-absorbing film.

As comparison, step (3) of this embodiment is replaced by the solvent annealing method, and the perovskite intermediate-phase film is placed on a hot plate at room temperature, 10 microliters of dimethylformamide solvent is dripped at a distance of 1 cm from the perovskite intermediate-phase film, the glass petri dish is used to cover the perovskite intermediate-phase film and the solvent, the heating switch of the hot plate is turned on to heat up at a rate of 40° C./min, after reaching 65° C., heating is maintained for 3 minutes, and the hot plate continues to heat up to 100° C. and heating is maintained for 10 minutes, so as to obtain a solvent-annealed wide-bandgap perovskite light-absorbing film.

As can be seen from FIG. 13, the wide-bandgap perovskite solar cell prepared by close space annealing has the highest efficiency, up to 18.58%. The wide-bandgap perovskite solar cell prepared by normal annealing has the lowest efficiency, of 17.22%. The wide-bandgap perovskite solar cell prepared by solvent annealing has the moderate efficiency, of 18.14%.

### Embodiment 5

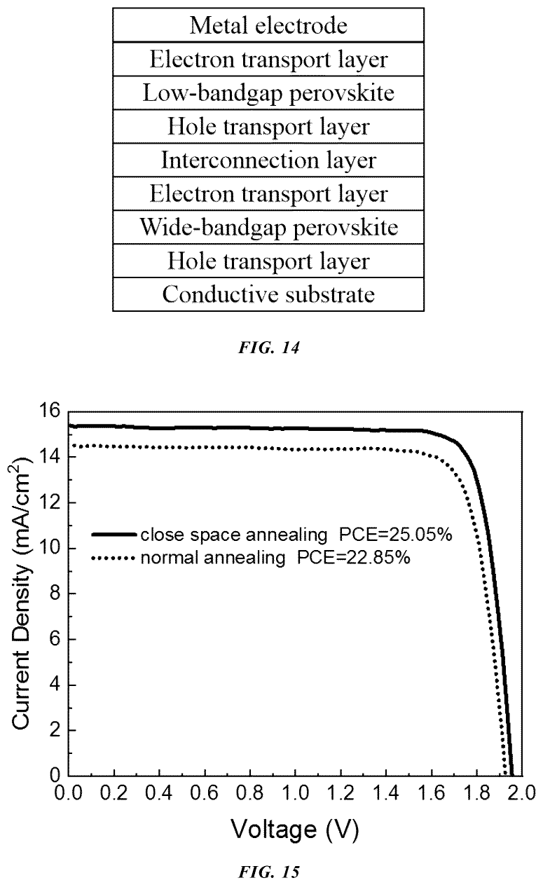

A method for preparing a tandem solar cell is provided. As shown in FIG. 14, the tandem solar cell is a planar structure, including a substrate, a hole transport layer, a wide-bandgap perovskite light-absorbing layer, an electron transport layer, an intermediate connection layer, a hole transport layer, a low-bandgap perovskite light-absorbing layer, an electron transport layer and a metal electrode. The substrate consists of a conductive substrate and a hole transport layer deposited on the front face thereof. The preparation method includes the following steps:

Step (1) A perovskite precursor solution is deposited on the substrate by spin coating to form a perovskite precursor film on the surface of the hole transport layer.

Spin coating parameters include a low speed of 500 rpm and a duration of 3 seconds, and a high speed of 4000 rpm and a duration of 60 seconds, and anti-solvent diethyl ether is dripped at the 25th second during the high speed period.

Step (2) The substrate is placed on a hot plate with the front face facing upward, and is heated at a first temperature of 65° C. for 3 minutes to obtain a perovskite intermediate-phase film.

Step (3) The hot plate is overlayed with a layer of permeable membrane. A perovskite intermediate-phase film containing residual solvent is placed on the permeable membrane with the back face facing upward, and the film is heated at a first temperature for 30 seconds, and then the temperature is raised to a second temperature of 100° C. at a heat-up rate of 40° C./min, and heating is maintained for 7 minutes after reaching 100° C.

Step (4) The substrate is placed on the hot plate with the front face facing upward and continues to be heated at the second temperature of 100° C. for 3 minutes to obtain a wide-bandgap perovskite light-absorbing layer.

Step (5) An electron transport layer, an intermediate connection layer and a hole transport layer are sequentially deposited on the surface of the perovskite light-absorbing layer.

Step (6) A perovskite precursor solution is coated over the surface of the hole transport layer in step (5) by spin coating.

Spin coating parameters include a low speed of 1000 rpm and a duration of 10 seconds, and a high speed of 4000 rpm and a duration of 60 seconds, and anti-solvent diethyl ether is dripped at the 7th second during the high speed period.

Step (7) A low-bandgap perovskite light-absorbing layer is prepared by the close space annealing method.

Step (8) An electron transport layer is deposited on the surface of the low-bandgap perovskite light-absorbing layer.

Step (9) A metal electrode is deposited on the surface of the hole transport layer by thermal evaporation to finally obtain a tandem solar cell.

The performance of the obtained all-perovskite two-end tandem solar cell is tested, and the specific conditions of J-V measurement include a scanning voltage range of −0.1-2.2 V, a step size of 10 mV and a scanning speed of 150 mV/s.

As comparison, step (3) and step (7) of this embodiment are replaced by the normal annealing method, and the perovskite intermediate-phase film is placed on a hot plate at 65° C. and heated for 3 minutes, then transferred to a hot plate at 100° C. and heated for 10 minutes, so as to obtain a normally annealed perovskite light-absorbing film.

As can be seen from FIG. 15, the tandem solar cell obtained by use of combination of a wide-bandgap perovskite light-absorbing layer and a low-bandgap perovskite light-absorbing layer both prepared by close space annealing has the highest efficiency, up to 25.05%. The tandem solar cell obtained by use of combination of a wide-bandgap perovskite light-absorbing layer and a low-bandgap perovskite light-absorbing layer both prepared by normal annealing has a low efficiency, of 22.85%.

It should be noted that the operation methods and steps in the performance test of the perovskite solar cell mentioned above in the present invention are all carried out according to the conventional methods in the field unless specifically limited or specified.

Described above are merely illustration and explanation of the structure of the present invention, and any modification or supplementation or substitution in similar manners made to the particular embodiments described above by those skilled in the art without any creative effort shall fall within the protection scope of this patent.

1. A close space annealing method, comprising:
step (1): depositing a perovskite precursor solution on a front face of a substrate by spin coating, and forming a perovskite precursor film on the front face of the substrate;
step (2): placing the substrate coated with the perovskite precursor film on a hot plate, the hot plate being in direct contact with a back face of the substrate, heat being sequentially transferred to the substrate and the perovskite precursor film; setting a temperature of the hot plate to a first temperature, controlling evaporated amount and residual amount of the solvent in the perovskite precursor film by controlling the first temperature and heating duration, so that the perovskite precursor material in the perovskite precursor film is crystallized into perovskite grains, forming a perovskite intermediate-phase film; and
step (3): overlaying the hot plate with a layer of permeable membrane, placing the perovskite intermediate-phase film containing residual solvent on the permeable membrane with the back face of the substrate facing upward, keeping the first temperature and continuing with heating, so that adjacent perovskite grains merge with each other during the volatilization of the residual solvents; and raising the temperature of the hot plate to a second heating temperature and continuing with heating, so that the perovskite grains undergo phase change to form a perovskite light-absorbing layer.

2. The close space annealing method of claim 1, wherein
an optical bandgap range of the perovskite material is between 1.2 and 2.3 electron volts; and
the permeable membrane is selected from a glass sheet, filter paper, printing paper and polymer film.

3. The close space annealing method of claim 2, wherein
the perovskite material is selected from the group consisting of methylammonium lead iodine, methylammonium lead bromide, formamidinium lead iodide, formamidinium lead bromide, formamidinium tin iodide, cesium lead iodide, cesium lead bromide and any combination thereof; and
the solvent is selected from the group consisting of dimethyl sulfoxide, dimethylformamide and gamma butyrolactone and any combination thereof.

4. The close space annealing method of claim 1, wherein
the perovskite precursor solution is a stable solution mixture formed by dissolving the perovskite material in the solvent by Lewis acid-base method.

5. The close space annealing method of claim 1, wherein
the spin coating in step (1) comprises:
a first step: setting a spinning speed to 500-1000 rpm and a duration to 2-10 seconds for the spin coating;
a second step: setting the spinning speed to 3000-5000 rpm and the duration to 1 minute for the spin coating; and dripping an anti-solvent 4-30 seconds after start of spinning in the second step.

6. The close space annealing method of claim 5, wherein
the anti-solvent is diethyl ether, or is selected from the group consisting of chlorobenzene, ethyl acetate, isopropanol and any combination thereof.

7. The close space annealing method of claim 1, wherein
in step (2), the first temperature is 60-70° C. and the heating duration is 10-50 seconds; and
in step (3), the heating duration is 2-4 minutes at the first temperature, and the second heating temperature is 80-120° C., and the heating duration is 6-15 minutes at the second heating temperature.

8. The close space annealing method of claim 1, further comprising:
step (4): placing the substrate on the hot plate with the front face facing upward, with the hot plate being in direct contact with the back face of the substrate; and maintaining heating at the second heating temperature for 1-3 minutes.

9. A method for preparing a perovskite film by using the close space annealing method of claim 1, the perovskite film being a low-bandgap perovskite film or a wide-bandgap perovskite film.

10. A method for preparing a solar cell by using the close space annealing method of claim 1, the solar cell being a low-bandgap perovskite solar cell, a wide-bandgap perovskite solar cell or a tandem solar cell.
